(19) United States
(12) Patent Application Publication
(10) Pub. No.: US 2026/0107419 A1
(43) Pub. Date: Apr. 16, 2026

(54) Redundant Liquid-Based Cooling System

(71) Applicant: Microsoft Technology Licensing, LLC, Redmond, WA (US)

(72) Inventors: Andrew D. Delano, Woodinville, WA (US); John J. Brzozowski, Schwenksville, PA (US); Siddharth Bhopte, Sammamish, WA (US); Yimin Zhang, Johns Creek, GA (US); Guixiang Tan, Portland, OR (US); Laurent A. Regimbal, Georgetown, TX (US)

(21) Appl. No.: 18/915,073

(22) Filed: Oct. 14, 2024

(51) Int. Cl. H05K 7/20; G06F 1/20

(52) U.S. Cl. CPC H05K 7/20781; G06F 1/20; H05K 7/20263; H05K 7/20272

(57) ABSTRACT

A liquid-based cooling system for cooling rack-mounted IT equipment including: a first liquid-based cooling device configured to provide a first quantity of cooled fluid to the rack-mounted IT equipment including: an output port configured to provide the first quantity of cooled fluid to the rack-mounted IT equipment, wherein the first quantity of cooled fluid is configured to absorb waste heat from the rack-mounted IT equipment to generate a first quantity of warmed fluid, and an input port configured to receive the first quantity of warmed fluid from the rack-mounted IT equipment and remove the waste heat from the first quantity of warmed fluid to generate the first quantity of cooled fluid; and at least a second liquid-based cooling device configured to provide at least a second quantity of cooled fluid to the rack-mounted IT equipment including: an output port configured to provide the at least a second quantity of cooled fluid to the rack-mounted IT equipment, wherein the at least a second quantity of cooled fluid is configured to absorb waste heat from the rack-mounted IT equipment to generate at least a second quantity of warmed fluid, and an input port configured to receive the at least a second quantity of warmed fluid from the rack-mounted IT equipment and remove the waste heat from the at least a second quantity of warmed fluid to generate the at least a second quantity of cooled fluid.

### TECHNICAL FIELD

This disclosure relates to liquid-based cooling systems and, more particularly, to redundant liquid-based cooling systems for data centers.

### BACKGROUND

The history of cooling data centers illustrates a continuous quest for more efficient thermal management solutions, evolving from simple air cooling to advanced liquid cooling technologies. Initially, early data centers in the mid-20th century used basic air conditioning systems to manage the heat generated by the relatively few and low-powered machines. As data centers expanded and the computational power increased, air cooling methods became more sophisticated. Innovations such as raised floors, which allowed for better airflow distribution, and the separation of cold aisles (where cool air is supplied) and hot aisles (where hot air is exhausted) significantly improved the efficiency of air cooling systems. These methods were sufficient for a time but began to show limitations as server densities and heat loads continued to rise.

The late 20th and early 21st centuries marked a turning point. The rapid growth of data processing needs, driven by the internet boom, big data, and the emergence of high-performance computing (HPC) and artificial intelligence (AI), required data centers to pack more servers into limited spaces. This increase in density led to greater heat output, challenging the capabilities of traditional air cooling systems. It became clear that air cooling alone could not keep up with the thermal demands without consuming excessive amounts of energy and compromising efficiency.

To address these challenges, the data center industry revisited liquid cooling, a technology first utilized in mid-20th-century mainframe computers like those from IBM. Liquid cooling offered superior thermal conductivity compared to air, making it much more efficient at removing heat from densely packed servers. Initially, liquid cooling technologies such as direct-to-chip cooling, which uses cold plates attached to individual components, and immersion cooling, where entire servers are submerged in a thermally conductive but non-electrically conductive liquid, began to gain traction.

Direct-to-chip cooling involves circulating a coolant directly over critical components like CPUs and GPUs, which are the primary sources of heat. This method allows for precise and efficient heat removal, significantly reducing the thermal resistance compared to air cooling. Immersion cooling takes this a step further by submerging entire server units in a special dielectric fluid, providing uniform cooling across all components and eliminating the need for air conditioning within the data center.

The adoption of liquid cooling has continued to grow, driven by its ability to handle higher heat densities, improve energy efficiency, and reduce overall cooling costs. Modern data centers, particularly those focusing on HPC and AI applications, increasingly rely on liquid cooling to maintain optimal performance while managing the substantial heat output. This transition from air to liquid cooling reflects not only technological advancements but also the industry's commitment to sustainability and operational efficiency. As data centers continue to evolve, liquid cooling is expected to play an even more significant role in enabling the next generation of computing power.

### BRIEF DESCRIPTION OF THE DRAWINGS

FIGS. 1-3 are diagrammatic views of a liquid-based cooling system according to an embodiment of the present disclosure.

Like reference symbols in the various drawings indicate like elements.

### DETAILED DESCRIPTION OF THE PREFERRED EMBODIMENTS

As discussed above, the use of liquid cooling at data centers has been growing, driven by its ability to handle higher heat densities, improve energy efficiency, and reduce overall cooling costs. Modern data centers, particularly those focusing on HPC and AI applications, increasingly rely on liquid cooling to maintain optimal performance while managing the substantial heat output. This transition from air to liquid cooling reflects not only technological advancements but also the industry's commitment to sustainability and operational efficiency. As data centers continue to evolve, liquid cooling is expected to play an even more significant role in enabling the next generation of computing power.

Unfortunately, all liquid cooling systems (regardless of their level of dependability and quality), eventually fail. And in the day of HPC and AI applications and the huge computational tasks performed by these computational systems, such tasks often take weeks (if not months) to perform. And in the event of a failure of such a liquid cooling system, this failure (regardless of how infrequent) may mandate the shut down of the computational equipment performing these computational tasks, resulting in a very large computational loss and an unhappy client.

As will be discussed below in greater detail, implementations of the present disclosure are configured to utilize a plurality of liquid-based cooling devices, thus providing a level of redundant cooling in the unlikely event of a failure of one of the liquid-based cooling devices.

### Liquid-Based Cooling System

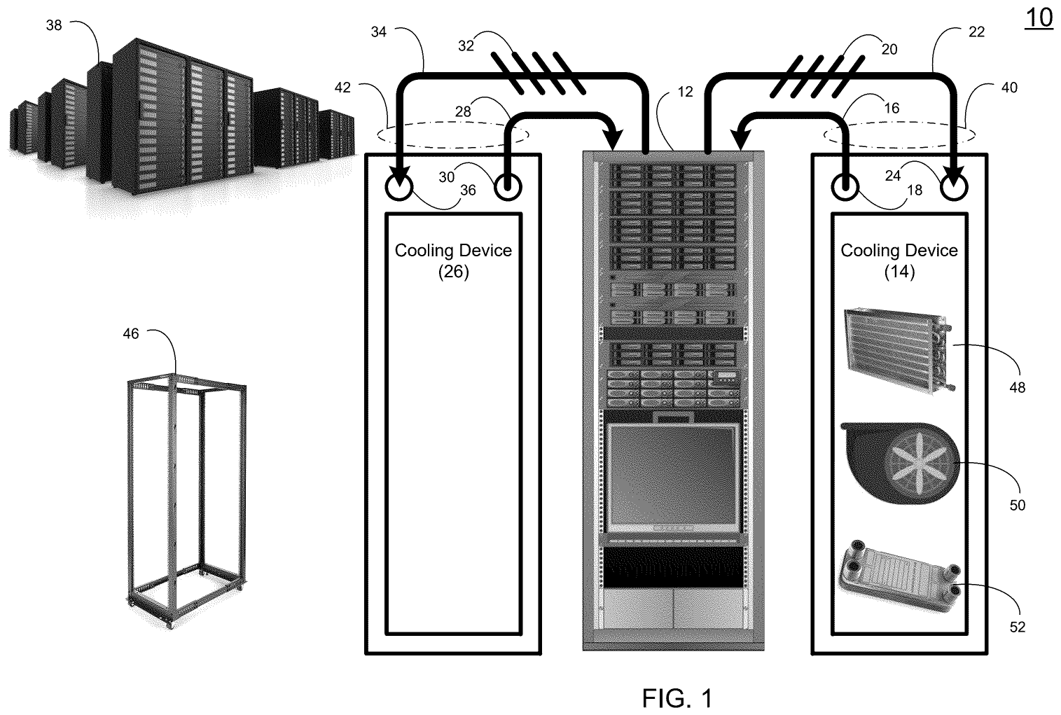

Referring to FIGS. 1-3, there is shown a liquid-based cooling system (e.g., liquid-based cooling system 10) for cooling rack-mounted IT equipment (e.g., rack-mounted IT equipment 12).

An example of the rack-mounted IT equipment (e.g., rack-mounted IT equipment 12) may include but is not limited to a plurality of servers.

A server is a powerful computer designed to process, manage, store, and deliver data, services, or applications to other computers, known as clients, over a network. These servers may play a critical role in data centers, enabling various digital services and applications to function efficiently. They may consist of high-performance processors (CPUs) to handle multiple tasks and users simultaneously, large amounts of RAM for fast data access and smooth application performance, and various storage options, including hard drives (HDDs) and solid-state drives (SSDs), to store large volumes of data. Advanced networking components facilitate high-speed data transfer within the data center and to external networks.

Servers may come in different types based on their functions. Web servers may deliver web pages to users'browsers, database servers may store and manage databases while handling queries and transactions, and application servers may run applications and deliver the necessary processing power and data to client machines. Other types may include file servers that store and manage files for multiple users, mail servers that manage and store emails, and virtualization servers that run virtual machines, allowing multiple operating systems and applications to run on a single physical server. Overall, servers are the backbone of a data center, providing the necessary infrastructure for hosting websites, running applications, storing data, and delivering services efficiently and reliably.

Another example of the rack-mounted IT equipment (e.g., rack-mounted IT equipment 12) may include but is not limited to one or more graphical processing units.

A Graphical Processing Unit (GPU) is a specialized electronic circuit designed to accelerate the processing of images and videos. Unlike a Central Processing Unit (CPU), which handles a wide range of tasks, a GPU is optimized for parallel processing, making it highly effective at handling the complex mathematical calculations required for rendering graphics. GPUs may be equipped with a large number of smaller, efficient cores that work together to perform multiple operations simultaneously, making them ideal for tasks that can be parallelized, such as rendering graphics and processing large datasets. Originally designed to accelerate the rendering of 3D graphics, GPUs may handle tasks like shading, texturing, and transforming vertices, essential for creating images in video games, movies, and other visual media. They may also be used for encoding and decoding video streams, enabling smooth playback and editing of high-definition videos.

Beyond graphics, modern GPUs may be used for general-purpose computing tasks, known as GPGPU (General-Purpose computing on Graphics Processing Units). This may include scientific simulations, machine learning, deep learning, and data mining, where their ability to handle parallel computations significantly speeds up processing times. A typical GPU architecture may include multiple cores, memory (VRAM), and various specialized units for handling different aspects of rendering and computation, designed to handle large volumes of data with high throughput. GPUs may be crucial in fields such as artificial intelligence, where they accelerate the training of neural networks, finance for high-frequency trading algorithms, and healthcare for medical imaging and genetic analysis. In summary, a GPU is a powerful and versatile processor designed for parallel computation and high-performance tasks, particularly those involving graphics and video, making it indispensable in various advanced computing applications.

The liquid-based cooling system (e.g., liquid-based cooling system 10) may include a first liquid-based cooling device (e.g., first liquid-based cooling device 14) configured to provide a first quantity of cooled fluid (e.g., first quantity of cooled fluid 16) to the rack-mounted IT equipment (e.g., rack-mounted IT equipment 12).

In computer liquid cooling systems, several types of fluids may be used to efficiently transfer heat away from critical components such as CPUs and GPUs. The most commonly used fluid is distilled water, prized for its high thermal conductivity and heat capacity. However, distilled water alone can pose risks such as corrosion and biological growth; hence, it is often mixed with additives. These additives may include anti-corrosives, biocides, and substances like glycols (e.g., propylene glycol or ethylene glycol), which adjust the boiling and freezing points, enhancing the coolant's stability across various temperatures. For more advanced applications, particularly where there is a risk of direct contact with electronic components, dielectric fluids may be used. These fluids are non-conductive and safe for direct interaction with electronics, making them ideal for immersion cooling systems. Examples may include fluorocarbon-based liquids, which, while more expensive, are highly effective at heat removal. Choosing the right cooling fluid may involve considering factors such as the system's heat output, environmental conditions, and maintenance requirements to ensure optimal performance and longevity of the cooling system.

The first liquid-based cooling device (e.g., first liquid-based cooling device 14) may include an output port (e.g., output port 18) configured to provide the first quantity of cooled fluid (e.g., first quantity of cooled fluid 16) to the rack-mounted IT equipment (e.g., rack-mounted IT equipment 12). This output port (e.g., output port 18) may be configured to support various types of couplers, examples of which include barbed couplers, compression couplers, and push in couplers. The first quantity of cooled fluid (e.g., first quantity of cooled fluid 16) may be configured to absorb waste heat (e.g., waste heat 20) from the rack-mounted IT equipment (e.g., rack-mounted IT equipment 12) to generate a first quantity of warmed fluid (e.g., first quantity of warmed fluid 22). For example, the first quantity of cooled fluid (e.g., first quantity of cooled fluid 16) may be circulated near/proximate one or more heat generating components (e.g., CPUs within the rack-mounted IT equipment 12) so that the waste heat (e.g., waste heat 20) may be absorbed.

The first liquid-based cooling device (e.g., first liquid-based cooling device 14) may also include an input port (e.g., input port 24) configured to receive the first quantity of warmed fluid (e.g., first quantity of warmed fluid 22) from the rack-mounted IT equipment (e.g., rack-mounted IT equipment 12) and remove the waste heat (e.g., waste heat 20) from the first quantity of warmed fluid (e.g., first quantity of warmed fluid 22) to generate the first quantity of cooled fluid (e.g., first quantity of cooled fluid 16). This input port (e.g., input port 24) may be configured to support various types of couplers, examples of which include barbed couplers, compression couplers, and push in couplers.

The liquid-based cooling system (e.g., liquid-based cooling system 10) may also include at least a second liquid-based cooling device (e.g., at least a second liquid-based cooling device 26) configured to provide at least a second quantity of cooled fluid (e.g., at least a second quantity of cooled fluid 28) to the rack-mounted IT equipment (e.g., rack-mounted IT equipment 12).

The at least a second liquid-based cooling device (e.g., at least a second liquid-based cooling device 26) may include an output port (. e., output port 30) configured to provide the at least a second quantity of cooled fluid (e.g., at least a second quantity of cooled fluid 28) to the rack-mounted IT equipment (e.g., rack-mounted IT equipment 12). The at least a second quantity of cooled fluid (e.g., at least a second quantity of cooled fluid 28) may be configured to absorb waste heat (e.g., waste heat 32) from the rack-mounted IT equipment (e.g., rack-mounted IT equipment 12) to generate at least a second quantity of warmed fluid (e.g., at least a second quantity of warmed fluid 34). For example, the second quantity of cooled fluid (e.g., second quantity of cooled fluid 28) may be circulated near/proximate one or more heat generating components (e.g., CPUs within rack-mounted IT equipment 12) so that the waste heat (e.g., waste heat 32) may be absorbed.

The at least a second liquid-based cooling device (e.g., at least a second liquid-based cooling device 26) may include an input port (e.g., input port 36) configured to receive the at least a second quantity of warmed fluid (e.g., at least a second quantity of warmed fluid 34) from the rack-mounted IT equipment (e.g., rack-mounted IT equipment 12) and remove the waste heat (e.g., waste heat 32) from the at least a second quantity of warmed fluid (e.g., at least a second quantity of warmed fluid 34) to generate the at least a second quantity of cooled fluid (e.g., at least a second quantity of cooled fluid 28).

The liquid-based cooling system (e.g., liquid-based cooling system 10), the first liquid-based cooling device (e.g., first liquid-based cooling device 14) and/or the at least a second liquid-based cooling device (e.g., at least a second liquid-based cooling device 26) may be configured to be positioned within and/or outside of a data center (e.g., data center 38). For example, the first liquid-based cooling device (e.g., first liquid-based cooling device 14) and/or the at least a second liquid-based cooling device (e.g., at least a second liquid-based cooling device 26) may be positioned within the data center (e.g., data center 38) in the same location (e.g., same room) as the rack-mounted IT equipment (e.g., rack-mounted IT equipment 12). Additionally/alternatively, the first liquid-based cooling device (e.g., first liquid-based cooling device 14) and/or the at least a second liquid-based cooling device (e.g., at least a second liquid-based cooling device 26) may be positioned in a different location than the rack-mounted IT equipment (e.g., rack-mounted IT equipment 12), such as in a different room/different building than the rack-mounted IT equipment (e.g., rack-mounted IT equipment 12).

A data center (e.g., data center 38) is a facility that houses a large number of computer servers and related equipment used to store, process, and disseminate data. These centers are critical infrastructure for modern businesses and organizations, supporting a wide range of digital services and applications. Data centers (e.g., data center 38) are typically large buildings with secure and climate-controlled environments, containing racks and cabinets to organize servers efficiently. The hardware may include powerful servers, storage devices like hard drives and solid-state drives, and networking equipment such as routers, switches, and cables for data transfer within the data center and to external networks. Backup power systems, like uninterruptible power supplies (UPS) and generators, may ensure continuous operation.

Environmental control may be crucial, with cooling systems maintaining optimal operating temperatures and fire suppression systems detecting and extinguishing fires without damaging equipment. Security measures may encompass both physical security, such as surveillance cameras, security personnel, and biometric access controls, and cybersecurity, including firewalls, intrusion detection systems, and encryption to protect data from cyber threats. Operational management may involve systems to monitor performance and health of equipment, regular maintenance schedules to prevent downtime and ensure reliability, and scalability to add more servers and storage as demand grows.

There are different types of data centers: enterprise data centers owned and operated by individual organizations for their own use, colocation data centers where multiple organizations rent space for their servers, and cloud data centers operated by cloud service providers like Amazon Web Services (AWS), Microsoft Azure, and Google Cloud. Services provided by data centers may include hosting websites, applications, and databases, offering scalable cloud computing resources and storage over the internet, and ensuring data backup and recovery in case of loss. Data centers are fundamental to the functioning of the internet and modern digital services, enabling everything from web hosting to big data analytics.

The first quantity of cooled fluid (e.g., first quantity of cooled fluid 16) and/or the at least a second quantity of cooled fluid (e.g., at least a second quantity of cooled fluid 28) may be provided directly to the rack-mounted IT equipment (e.g., rack-mounted IT equipment 12), as shown in FIG. 1.

For example, each of the first liquid-based cooling device (e.g., first liquid-based cooling device 14) and/or the at least a second liquid-based cooling device (e.g., at least a second liquid-based cooling device 26) may be configured to be directly plumbed to the rack-mounted IT equipment (e.g., rack-mounted IT equipment 12) via one or more hoses/pipes/conduits (e.g., hoses/pipes/conduits 40, 42), thus providing the first quantity of cooled fluid (e.g., first quantity of cooled fluid 16) and/or the at least a second quantity of cooled fluid (e.g., at least a second quantity of cooled fluid 28) directly to the rack-mounted IT equipment (e.g., rack-mounted IT equipment 12).

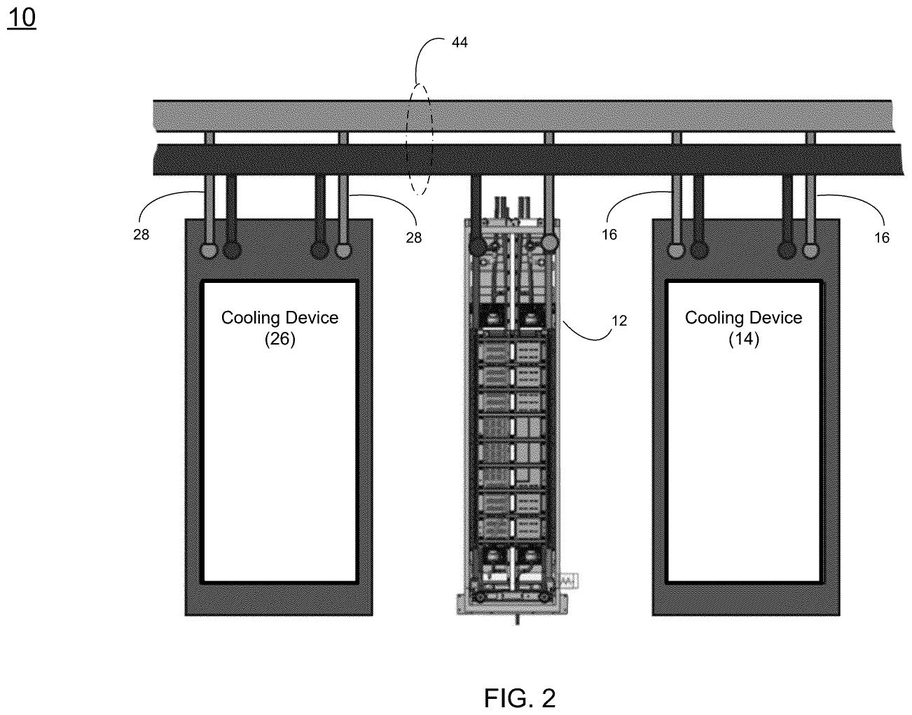

Additionally/alternatively, the first quantity of cooled fluid (e.g., first quantity of cooled fluid 16) and/or the at least a second quantity of cooled fluid (e.g., at least a second quantity of cooled fluid 28) may be provided to the rack-mounted IT equipment (e.g., rack-mounted IT equipment 12) via a manifold assembly (e.g., manifold assembly 44), as shown n FIG. 2.

For example, each of the first liquid-based cooling device (e.g., first liquid-based cooling device 14) and/or the at least a second liquid-based cooling device (e.g., at least a second liquid-based cooling device 26) may be plumbed to a common manifold system (e.g., common manifold system 44) that is fluidly coupled to the rack-mounted IT equipment (e.g., rack-mounted IT equipment 12), thus providing the first quantity of cooled fluid (e.g., first quantity of cooled fluid 16) and/or the at least a second quantity of cooled fluid (e.g., at least a second quantity of cooled fluid 28) to the rack-mounted IT equipment (e.g., rack-mounted IT equipment 12) via the common manifold system (e.g., common manifold system 44).

A manifold assembly (e.g., common manifold system 44) in the context of fluid distribution is a system designed to manage and direct the flow of fluids, such as liquids or gases, from a single input source to multiple output channels or from multiple input sources to a single output. The primary function of a manifold may be to distribute fluid efficiently, allowing for precise control and monitoring of fluid flow, pressure, and temperature. Manifolds may offer significant advantages, including streamlined fluid distribution, improved control over flow rate and pressure, and easier maintenance and troubleshooting. Types of manifolds may include parallel manifolds, which may distribute fluid simultaneously to different destinations, and series manifolds, which may distribute fluid sequentially from one port to the next.

In certain embodiments, the first liquid-based cooling device (e.g., first liquid-based cooling device 14) and/or the at least a second liquid-based cooling device (e.g., at least a second liquid-based cooling device 26) may be a rack-mounted liquid-based cooling device. For example, the first liquid-based cooling device (e.g., first liquid-based cooling device 14) and/or the at least a second liquid-based cooling device (e.g., at least a second liquid-based cooling device 26) may be configured to fit/be mounted within a standard computer equipment rack (e.g., computer equipment rack 46).

Rack-mounted equipment may refer to hardware devices designed to be securely installed in a standardized frame or enclosure known as a rack (e.g., computer equipment rack 46), commonly used in data centers, server rooms, and telecommunications facilities. These racks are typically 19 inches wide and have heights that are multiples of rack units (U), where one rack unit is equivalent to 1.75 inches. This standardization ensures compatibility and interchangeability among various equipment from different manufacturers, such as servers, network switches, routers, patch panels, power distribution units (PDUs), uninterruptible power supplies (UPS), and storage devices. Mounting hardware in this manner maximizes vertical space usage, allowing more equipment to be housed in a smaller footprint, which is essential for managing dense and complex network environments. Additionally, rack-mounted setups may aid in organizing and securing cables and components, improving airflow and cooling efficiency to maintain optimal operational temperatures and prevent overheating. Racks may often include features like locking doors and side panels to enhance security and protect sensitive equipment. This system's modularity and scalability make expanding or modifying the technological infrastructure straightforward, accommodating growing or changing business needs.

In certain embodiments, the first liquid-based cooling device (e.g., first liquid-based cooling device 14) and/or the at least a second liquid-based cooling device (e.g., at least a second liquid-based cooling device 26) may include: a liquid-to-air heat exchanger (e.g., liquid-to-air heat exchanger 48).

A liquid-to-air heat exchanger (e.g., liquid-to-air heat exchanger 48) is a device designed to facilitate the transfer of heat between a liquid and air. It may consist of a system of tubes or coils which contain the liquid—often water, glycol solutions, or other types of coolant. This tubing system may be encased within a housing that directs airflow around the tubes, typically with the aid of fans or blowers to enhance the efficiency of the heat transfer process. In practical applications, the heat exchanger may function by allowing the hot liquid to flow through the tubes. As air passes over these tubes, heat from the liquid is transferred to the air, cooling the liquid and warming the air.

Accordingly and in such a configuration, the first liquid-based cooling device (e.g., first liquid-based cooling device 14) and/or the at least a second liquid-based cooling device (e.g., at least a second liquid-based cooling device 26) may include: one or more fan assemblies (e.g., one or more fan assemblies 50).

A fan assembly (e.g., one or more fan assemblies 50) is a crucial component designed to move air or gases within various environments and systems, such as computers, automotive engines, HVAC systems, and industrial machinery. It may consist of a motor, fan blades or impellers, a housing or frame, and often includes additional elements like bearings and a fan guard. The motor may power the fan blades, which rotate to create airflow. This airflow may be used for cooling critical components, providing ventilation, or exhausting unwanted air or gases from a space. Fan assemblies are integral in maintaining the right operating temperatures and ensuring that electronic and mechanical components function efficiently and safely within their operational environments.

In certain embodiments, the first liquid-based cooling device (e.g., first liquid-based cooling device 14) and/or the at least a second liquid-based cooling device (e.g., at least a second liquid-based cooling device 26) may include: a liquid-to-liquid heat exchanger (e.g., liquid-to-liquid heat exchanger 52).

A liquid-to-liquid heat exchanger (e.g., liquid-to-liquid heat exchanger 52) is a device designed to transfer heat between two separate liquid streams without allowing them to mix together. This type of heat exchanger is widely used in various applications such as heating, cooling, and temperature control processes in industries like chemical manufacturing, power generation, pharmaceuticals, and HVAC systems.

The construction of a liquid-to-liquid heat exchanger may involve a series of tubes or plates that form two separate channels for the liquids. One common design is the shell and tube heat exchanger, where one liquid flows through a set of tubes and the second liquid flows around these tubes within a larger shell. The heat transfer may occur across the tube walls, with one liquid heating up as it absorbs heat from the other, which consequently cools down.

The effectiveness of a liquid-to-liquid heat exchanger may depend on several factors including the properties of the liquids, the surface area of the heat transfer components, the flow arrangement (counterflow, parallel flow, or crossflow), and the temperature gradient between the two liquids. These devices may play a crucial role in optimizing thermal management and energy conservation.

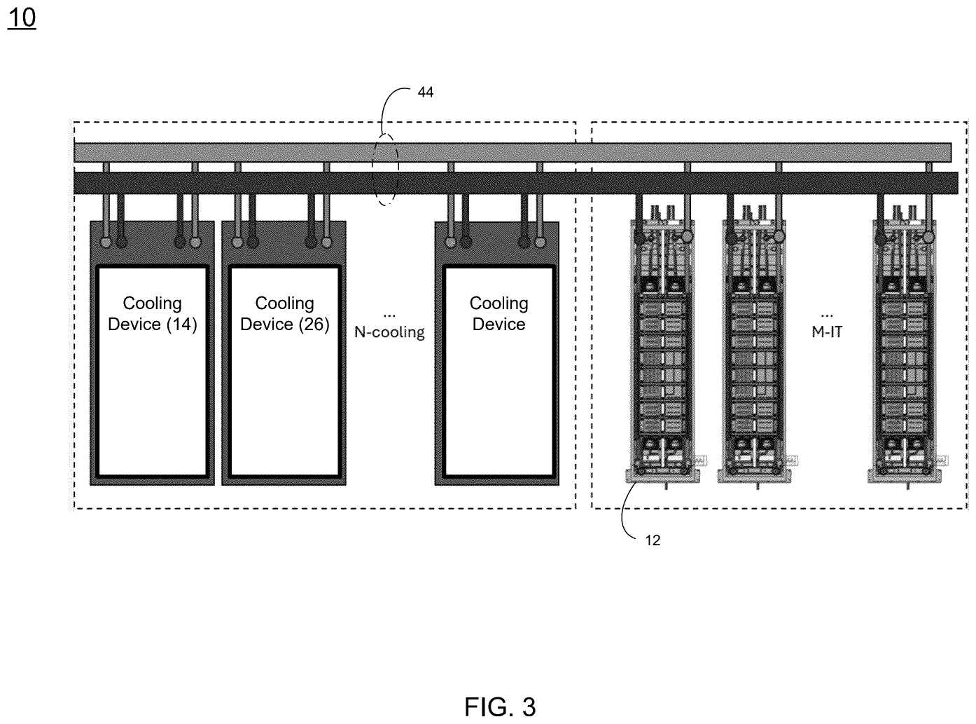

As shown in FIG. 3. the quantity of liquid-based cooling devices (e.g., for a given IT load) may be adjusted upward or downward to balance redundancy versus cost. Naturally, if a high level of redundancy is required, two liquid-based cooling devices may be utilized for each piece of rack-mounted IT equipment (e.g., rack-mounted IT equipment 12). However, the cost may quickly become prohibitive. Conversely, if cost is the primary motivator, two liquid-based cooling devices may be utilized for e.g., every twenty pieces of rack-mounted IT equipment (e.g., rack-mounted IT equipment 12). However, the redundancy level may be too low to provide meaningful protection. Accordingly, the level of redundancy may be adjusted upward or downward based upon e.g., the redundancy level required, the cost associated with such redundancy, the cooling capacity of each liquid-based cooling device, and the thermal load of each piece of rack-mounted IT equipment (e.g., rack-mounted IT equipment 12).

### System Overview

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A liquid-based cooling system for cooling rack-mounted IT equipment comprising:
a first liquid-based cooling device configured to provide a first quantity of cooled fluid to the rack-mounted IT equipment including:
an output port configured to provide the first quantity of cooled fluid to the rack-mounted IT equipment, wherein the first quantity of cooled fluid is capable of absorbing waste heat from the rack-mounted IT equipment to generate a first quantity of warmed fluid, and
an input port configured to receive the first quantity of warmed fluid from the rack-mounted IT equipment and remove the waste heat from the first quantity of warmed fluid to generate the first quantity of cooled fluid; and
at least a second liquid-based cooling device configured to provide at least a second quantity of cooled fluid to the rack-mounted IT equipment including:
an output port configured to provide the at least a second quantity of cooled fluid to the rack-mounted IT equipment, wherein the at least a second quantity of cooled fluid is capable of absorbing waste heat from the rack-mounted IT equipment to generate at least a second quantity of warmed fluid, and
an input port configured to receive the at least a second quantity of warmed fluid from the rack-mounted IT equipment and remove the waste heat from the at least a second quantity of warmed fluid to generate the at least a second quantity of cooled fluid.

2. The liquid-based cooling system of claim 1 wherein the rack-mounted IT equipment includes a plurality of servers.

3. The liquid-based cooling system of claim 1 wherein the rack-mounted IT equipment includes one or more graphical processing units.

4. The liquid-based cooling system of claim 1 wherein the first quantity of cooled fluid and/or the at least a second quantity of cooled fluid is provided directly to the rack-mounted IT equipment.

5. The liquid-based cooling system of claim 1 wherein the first quantity of cooled fluid and/or the at least a second quantity of cooled fluid is provided to the rack-mounted IT equipment via a manifold assembly.

6. The liquid-based cooling system of claim 1 wherein the first liquid-based cooling device and/or the at least a second liquid-based cooling device is a rack-mounted liquid-based cooling device.

7. The liquid-based cooling system of claim 1 wherein the first liquid-based cooling device and/or the at least a second liquid-based cooling device includes: a liquid-to-liquid heat exchanger.

8. The liquid-based cooling system of claim 1 wherein the first liquid-based cooling device and/or the at least a second liquid-based cooling device includes: a liquid-to-air heat exchanger.

9. The liquid-based cooling system of claim 8 wherein the first liquid-based cooling device and/or the at least a second liquid-based cooling device includes: one or more fan assemblies.

10. The liquid-based cooling system of claim 1 wherein the first liquid-based cooling device and/or the at least a second liquid-based cooling device is configured to be positioned within a data center.

11. The liquid-based cooling system of claim 1 wherein the first liquid-based cooling device and/or the at least a second liquid-based cooling device is configured to be positioned outside of a data center.

12. A liquid-based cooling system for cooling rack-mounted IT equipment, wherein the rack-mounted IT equipment includes a plurality of servers, comprising:
a first liquid-based cooling device configured to provide a first quantity of cooled fluid to the rack-mounted IT equipment including:
an output port configured to provide the first quantity of cooled fluid to the rack-mounted IT equipment, wherein the first quantity of cooled fluid is capable of absorbing waste heat from the rack-mounted IT equipment to generate a first quantity of warmed fluid, and
an input port configured to receive the first quantity of warmed fluid from the rack-mounted IT equipment and remove the waste heat from the first quantity of warmed fluid to generate the first quantity of cooled fluid; and
at least a second liquid-based cooling device configured to provide at least a second quantity of cooled fluid to the rack-mounted IT equipment including:
an output port configured to provide the at least a second quantity of cooled fluid to the rack-mounted IT equipment, wherein the at least a second quantity of cooled fluid is capable of absorbing waste heat from the rack-mounted IT equipment to generate at least a second quantity of warmed fluid, and
an input port configured to receive the at least a second quantity of warmed fluid from the rack-mounted IT equipment and remove the waste heat from the at least a second quantity of warmed fluid to generate the at least a second quantity of cooled fluid;
wherein the first quantity of cooled fluid and/or the at least a second quantity of cooled fluid is provided directly to the rack-mounted IT equipment.

13. The liquid-based cooling system of claim 12 wherein the rack-mounted IT equipment includes one or more graphical processing units.

14. The liquid-based cooling system of claim 12 wherein the first liquid-based cooling device and/or the at least a second liquid-based cooling device includes: a liquid-to-air heat exchanger.

15. The liquid-based cooling system of claim 14 wherein the first liquid-based cooling device and/or the at least a second liquid-based cooling device includes: one or more fan assemblies.

16. The liquid-based cooling system of claim 12 wherein the first liquid-based cooling device and/or the at least a second liquid-based cooling device is configured to be positioned within a data center.

17. The liquid-based cooling system of claim 12 wherein the first liquid-based cooling device and/or the at least a second liquid-based cooling device is configured to be positioned outside of a data center.

18. A liquid-based cooling system for cooling rack-mounted IT equipment, wherein the rack-mounted IT equipment includes plurality of servers, comprising:
a first liquid-based cooling device configured to provide a first quantity of cooled fluid to the rack-mounted IT equipment including:
an output port configured to provide the first quantity of cooled fluid to the rack-mounted IT equipment, wherein the first quantity of cooled fluid is capable of absorbing waste heat from the rack-mounted IT equipment to generate a first quantity of warmed fluid, and
an input port configured to receive the first quantity of warmed fluid from the rack-mounted IT equipment and remove the waste heat from the first quantity of warmed fluid to generate the first quantity of cooled fluid; and
at least a second liquid-based cooling device configured to provide at least a second quantity of cooled fluid to the rack-mounted IT equipment including:
an output port configured to provide the at least a second quantity of cooled fluid to the rack-mounted IT equipment, wherein the at least a second quantity of cooled fluid is capable of absorbing waste heat from the rack-mounted IT equipment to generate at least a second quantity of warmed fluid, and
an input port configured to receive the at least a second quantity of warmed fluid from the rack-mounted IT equipment and remove the waste heat from the at least a second quantity of warmed fluid to generate the at least a second quantity of cooled fluid;
wherein the first quantity of cooled fluid and/or the at least a second quantity of cooled fluid is provided to the rack-mounted IT equipment via a manifold assembly.

19. The liquid-based cooling system of claim 18 wherein the first liquid-based cooling device and/or the at least a second liquid-based cooling device is configured to be positioned within a data center.

20. The liquid-based cooling system of claim 18 wherein the first liquid-based cooling device and/or the at least a second liquid-based cooling device is configured to be positioned outside of a data center.
